(19) United States
(12) Patent Application Publication
(10) Pub. No.: US 2010/0328923 A1
(43) Pub. Date: Dec. 30, 2010

(54) MULTIPLE LAYER PHOSPHOR BEARING FILM

(75) Inventor: Alex Shaikevitch, Sunnyvale, CA (US)

Correspondence Address: Arent Fox LLP, 555 West Fifth Street, 48th Floor, Los Angeles, CA, 90013, US

(73) Assignee: Bridgelux, Inc., Sunnyvale, CA (US)

(21) Appl. No.: 12/492,135

(22) Filed: Jun. 25, 2009

(51) Int. Cl. F21V 9/16; H01L 21/56; B32B 7/12; B32B 9/00; B32B 7/02

(52) U.S. Cl. 362/84; 438/27; 428/343; 428/41.8; 428/212; 257/E21.499

(57) ABSTRACT

A multiple layer phosphor bearing film having a phosphor bearing layer comprising phosphor. The film may also have an optical layer having a refractive index that is higher than a refractive index for the phosphor bearing layer. The phosphor beraing layer may be adhesive to enable the film to be applied to a light source.

### BACKGROUND

1. Field

The present disclosure relates to multiple layer phosphor bearing film for solid state lighting devices.

2. Background

Solid state devices, such as light emitting diodes (LED)s, are attractive candidates for replacing conventional light sources such as incandescent and fluorescent lamps. LEDs have substantially higher light conversion efficiencies than incandescent lamps and longer lifetimes than both types of conventional light sources. In addition, some types of LEDs now have higher conversion efficiencies than fluorescent light sources and still higher conversion efficiencies have been demonstrated in the laboratory. Finally, LEDs require lower voltages than fluorescent lamps, and therefore, provide various power saving benefits.

Unfortunately, LEDs produce light in a relatively narrow spectrum. To replace conventional lighting systems, LED-based sources that produce white light are needed. One way to produce white light is to encapsulate blue or ultra-violet (UV) LEDs in a phosphor material. The phosphor material converts monochromatic light emitted from the blue or UV LEDs to broad-spectrum white light. The phosphor material is generally formed by encapsulating the LEDs with a carrier (e.g., epoxy or silicone), introducing a suspension of phosphor particles into the carrier, and then curing the carrier to provide a solid layer of material in which the phosphor particles will remain suspended. Various processes for suspending phosphor particles in epoxy or silicone carriers are known in the art.

Using these processes, it is difficult to achieve consistent mechanical and optical properties. Often, due to the process of suspending the phosphor particles in the carrier, the uniformity of light across the LEDs is difficult to maintain. The process itself is often time consuming and costly, requiring multiple fabrication steps to complete the process. Accordingly, there is a need in the art for improved processes for applying a phosphor material to LEDs and other solid state lighting devices.

### SUMMARY

In one aspect of the disclosure, a film includes a phosphor bearing layer comprising phosphor, the phosphor bearing layer being adhesive to enable the film to be applied to a light source. The film further includes a transparent protective layer on the phosphor bearing layer.

In another aspect of the disclosure, a film includes a phosphor bearing layer comprising phosphor, and a transparent protective layer on the phosphor bearing layer, the transparent protective layer comprising a refractive index that is higher than a refractive index for the phosphor bearing layer.

In yet another aspect of the disclosure, a light emitting device includes a light source, and a film comprising a transparent protective layer and a phosphor bearing layer on the transparent protective layer, the phosphor bearing layer being adhesive to adhere the film to the light source.

In a further aspect of the disclosure, a method of manufacturing a light emitting device includes applying a film to a light source, the film comprising a transparent protective layer and a phosphor bearing layer comprising phosphor, the phosphor bearing layer being adhesive to adhere the film to the light source.

It is understood that other aspects of the present invention will become readily apparent to those skilled in the art from the following detailed description, wherein it is shown and described only several aspects of a multilayer phosphor bearing film by way of illustration. As will be realized, the various aspects of the multilayer phosphor bearing film presented throughout this disclosure are capable of modification in various other respects, all without departing from the spirit and scope of the present invention. Accordingly, the drawings and the detailed description are to be regarded as illustrative in nature and not as restrictive.

### BRIEF DESCRIPTION OF THE FIGURES

Various aspects of the present invention are illustrated by way of example, and not by way of limitation, in the accompanying drawings, wherein:

FIG. 1 is a conceptual cross-sectional view illustrating an example of a light source;

FIG. 2 is a conceptual cross-sectional view illustrating an example of a light source with a multilayer phosphor bearing film;

FIG. 3A is a conceptual cross-section view illustrating an example of a process for manufacturing a multilayer phosphor bearing film; and

FIG. 4 is a conceptual perspective view illustrating an example of a process for manufacturing a light source with a multi layer phosphor bearing film.

### DETAILED DESCRIPTION

The present invention is described more fully hereinafter with reference to the accompanying drawings, in which various aspects of the present invention are shown. This invention, however, may be embodied in many different forms and should not be construed as limited to the various aspects of the present invention presented throughout this disclosure. Rather, these aspects are provided so that this disclosure will be thorough and complete, and will fully convey the scope of the present invention to those skilled in the art.

The various aspects of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus (e.g., device) or method.

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower”, can therefore, encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items

Various aspects of a multilayer phosphor bearing film for a solid state lighting device will now be presented. However, as those skilled in the art will readily appreciate, these aspects may be extended to other film applications without departing from the spirit and scope of the invention. The film may include a phosphor bearing layer with phosphor. The phosphor bearing layer may be adhesive to enable the film to be applied to a light source. The film may also include a transparent protective layer on the phosphor bearing layer. The phosphor bearing layer may include phosphor particles in a low-refractive index material, such as epoxy or silicone. A low-refractive index material provides a film with good mechanical strength. The transparent protective layer has a high refractive index, thereby providing good optical performance.

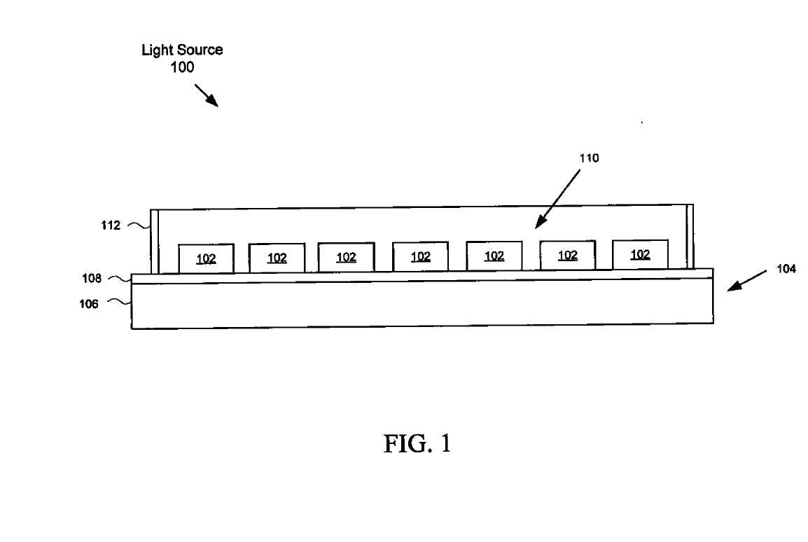

An example of a light source that is well suited for use with the multilayer phosphor bearing film will now be presented with reference to FIG. 1. However, as those skilled in the art will readily appreciate, the film may be used with other light sources, as well as other applications that could benefit from a phosphor bearing layer. Turing to FIG. 1, a light source 100 is shown with a number of light emitting cells 102 formed on a substrate 104 by means well known in the art. An LED is one example of a light emitting cell. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes, which is referred to as n-type or a p-type semiconductor region, respectively. In an LED application, the semiconductor includes an n-type semiconductor region and a p-type semiconductor region. A reverse electric field is created at the junction between the two regions, which cause the electrons and holes to move away from the junction to form an active region. When a forward voltage sufficient to overcome the reverse electric field is applied across the p-n junction, electrons and holes are forced into the active region and combine. When electrons combine with holes, they fall to lower energy levels and release energy in the form of light. LEDs are well known in the art, and therefore, will not be discussed any further.

The substrate 104 may include a base 106 and a dielectric layer 108. The base 106 provides mechanical support for the LEDs 102 and may be made from any suitable thermally conductive material, such as, by way of example, aluminum to dissipate heat away from the LEDs 102. The dielectric layer 108 may also be thermally conductive, while at the same time providing electrical insulation between the LEDs 102 from the base 108. The LEDs 102 may be electrically coupled in parallel and/or series by a copper circuit layer (not shown) on the dielectric layer 108. The LEDs 102 may be encapsulated in an encapsulation material 110, such as an epoxy, silicone, or other transparent encapsulation material. The encapsulation material 110 may be used to focus the light emitted from the LEDs 102, as well as protect the LEDs 102 from the environment. A structural boundary 112 (e.g., a ring) may be used to support the encapsulation material 110.

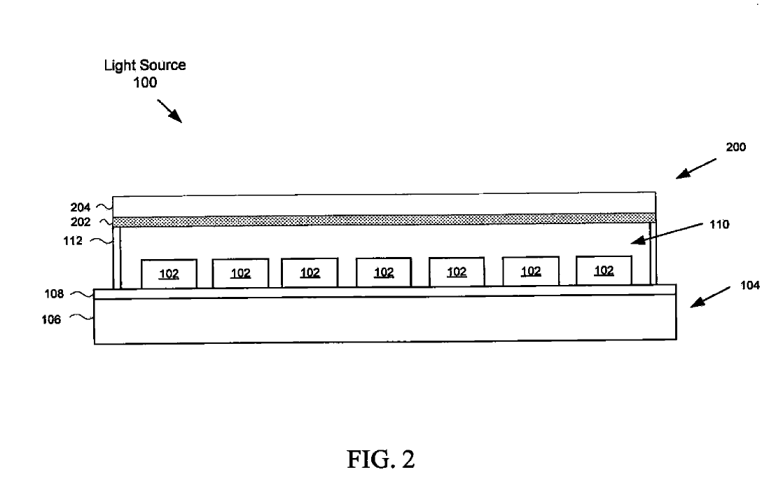

A multilayer phosphor bearing film may be applied to the light source. An example will now be presented with reference to FIG. 2. As discussed earlier, the film 200 may include a phosphor bearing layer 202 and a transparent protective layer 204. The phosphor bearing layer 202 may include phosphor particles in a low-refractive index material, such as epoxy or silicone. A low-refractive index material provides a film with good mechanical strength. The transparent protective layer 204 has a high refractive index, thereby providing good optical performance. The phosphor bearing layer 202 is adhesive so that it may be applied directly to the encapsulation material 110. Alternatively, the film 200 may include a separate adhesive layer either on the phosphor bearing layer 202 or on the transparent protective layer 204. In this example, the film 200 is adhered to the encapsulation material 110, but may be directly applied to the LEDs 102 in other applications.

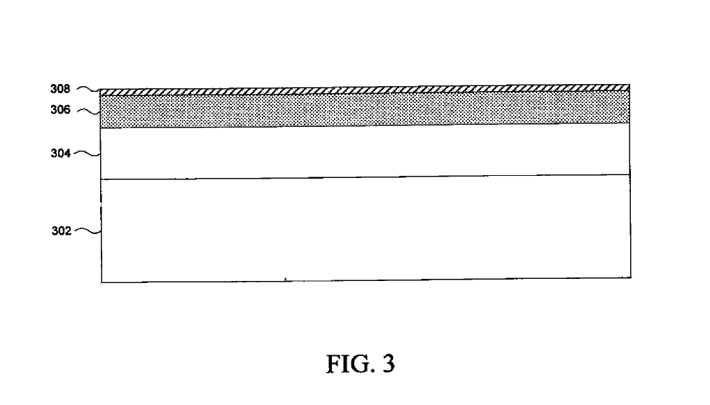

A process for manufacturing a multilayer phosphor bearing film will now be presented with reference to FIG. 3. The process begins with a substrate 302, such as glass or other suitable material. An applicator or other tool may be used to apply a silicone release coating to the substrate 302. The silicone coated substrate 302 is then cured. Once cured, a transparent protective layer 304 is formed by applying a thick highly refractive index material (e.g., silicone) on the substrate 302 with an applicator or other suitable tool. The transparent protective layer 304 is then partially cured. Next, a phosphor bearing layer 306 is formed by mixing phosphor particles with a low refractive index material to uniformly distribute the phosphor particles. The material may be a soft silicone with adhesive properties. Additives may then be introduced to stabilize the mixture. A thin phosphor bearing layer 306 is then applied to the partially cured transparent protective layer 304 with an applicator or other suitable tool and then cured. A removable backing material 308 may then be prepared by applying a silicone release coating to paper using an applicator or other suitable tool. The removable backing material 308 is then applied to the phosphor bearing layer 306. The substrate 302 is removed from the transparent protective layer to form the multilayer phosphor bearing film. The multilayer phosphor bearing film may be stored and/or distributed to lighting manufacturers in film sheets or film rolls.

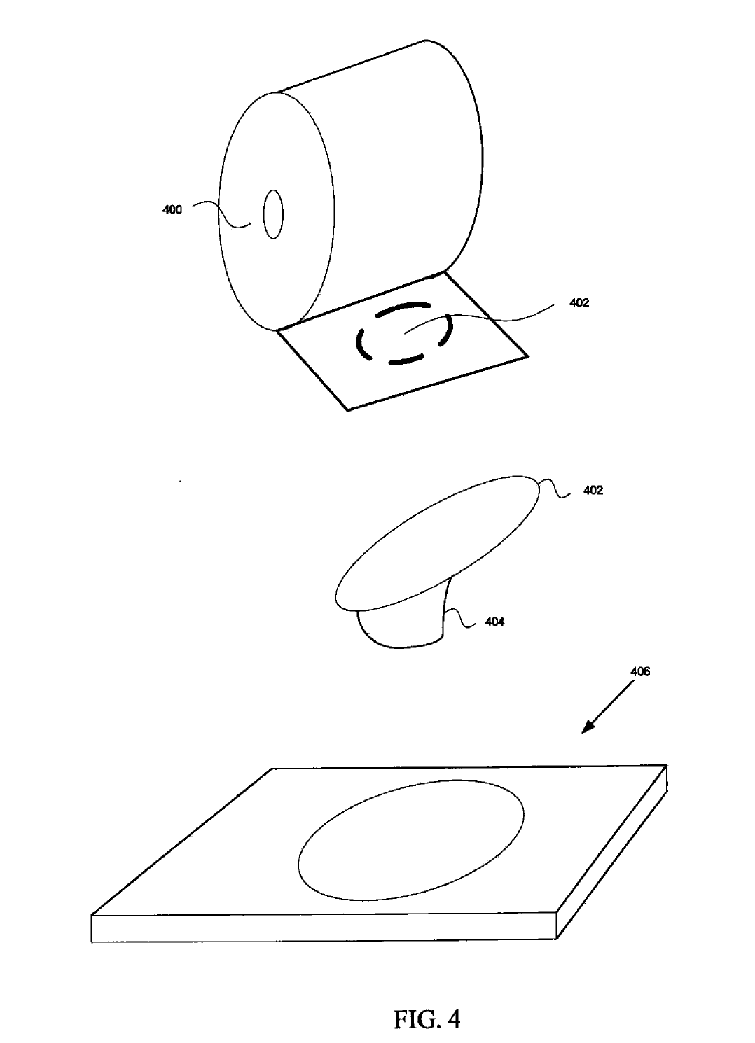

A process for manufacturing a manufacturing a light source with a multilayer phosphor bearing film will now be presented with reference to FIG. 4. In this example, a circular disk-shaped multilayer phosphor bearing film 402 may be cut or stamped out from a film roll 400. The backing material 404 may then be peeled from the circular disk-shaped film 402 to expose the phosphor bearing layer and then applied to the light source 406. This process may be automated using a conveyer belt manufacturing process or by some other means.

The various aspects of a multilayer phosphor bearing film are provided to enable one of ordinary skill in the art to practice the present invention. Various modifications to, and alternative configurations of, the multilayer phosphor bearing films presented throughout this disclosure will be readily apparent to those skilled in the art, and the concepts disclosed herein may be extended to other lighting applications. Thus, the claims are not intended to be limited to the various aspects of this disclosure, but are to be accorded the fill scope consistent with the language of the claims.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A film, comprising:
a phosphor bearing layer comprising phosphor, the phosphor bearing layer being adhesive to enable the film to be applied to a light source; and
a transparent protective layer on the phosphor bearing layer.

2. The film of claim 1 wherein the transparent protective layer comprises a refractive index that is higher than a refractive index for the phosphor bearing layer.

3. The film of claim 1 wherein the phosphor comprises phosphor particles and the phosphor bearing layer comprises a carrier with the phosphor particles.

4. The film of claim 3 wherein the carrier comprises silicone.

5. The film of claim 1 wherein the transparent protective layer comprises silicone.

6. The film of claim 1 further comprising a removable backing material attached to the phosphor bearing layer.

7. The film of claim 6 wherein the removable backing material comprises paper having a silicone release coating.

8. A film, comprising:
a phosphor bearing layer comprising phosphor; and
a transparent protective layer on the phosphor bearing layer, the transparent protective layer comprising a refractive index that is higher than a refractive index for the phosphor bearing layer.

9. The film of claim 8 wherein the phosphor bearing layer is adhesive to enable the film to be applied to a light source.

10. The film of claim 8 wherein the phosphor comprises phosphor particles and the phosphor bearing layer comprises a carrier with the phosphor particles.

11. The film of claim 10 wherein the carrier comprises silicone.

12. The film of claim 8 wherein the transparent protective layer comprise silicone.

13. The film of claim 8 further comprising a removable backing material attached to the adhesive layer.

14. The film of claim 12 wherein the removable backing material comprises paper having a silicone release coating.

15. A light emitting device, comprising:
a light source; and
a film comprising a transparent protective layer and a phosphor bearing layer on the transparent protective layer, the phosphor bearing layer being adhesive to adhere the film to the light source.

16. The light emitting device of claim 15 wherein the light source comprises one or more light emitting diodes.

17. The light emitting device of claim 16 wherein the light source further comprises an encapsulation material encapsulating the one or more light emitting diodes, the film being applied to the encapsulation material.

18. The light emitting device of claim 15 wherein the transparent protective layer comprises a refractive index which is higher than a refractive index for the phosphor bearing layer.

19. The light emitting device of claim 15 wherein the phosphor comprises phosphor particles and the phosphor bearing layer comprises a carrier with the phosphor particles.

20. The light emitting device of claim 19 wherein the carrier comprises silicone.

21. The light emitting device of claim 15 wherein the transparent protective layer comprise silicone.

22. A method of manufacturing a light emitting device, comprising:
applying a film to a light source, the film comprising a transparent protective layer and a phosphor bearing layer comprising phosphor, the phosphor bearing layer being adhesive to adhere the film to the light source.

23. The method of claim 22 further comprising removing backing material from the film to expose the phosphor bearing layer before applying the film to the light source.

24. The method of claim 22 further comprising cutting the film from a film sheet before applying the film to the light source.

25. The method of claim 22 further comprising cutting the film from a film roll before applying the film to the light source.

26. The method of claim 22 further comprising fabricating the light source with one or more light emitting diodes.

27. The method of claim 26 wherein the light source is further fabricated by encapsulating the one or more light emitting diodes with an encapsulation material.

28. The method of claim 22 wherein the light source comprises one or more LEDs encapsulated in an encapsulation material, and wherein the film is applied to the light source by applying the film to the encapsulation material.

30. The method of claim 22 wherein the transparent protective layer comprises a refractive index which is higher than a refractive index for the phosphor bearing layer.

31. The method of claim 22 wherein the phosphor comprises phosphor particles and the phosphor bearing layer comprises a carrier with the phosphor particles.

32. The method of claim 31 wherein the carrier comprises silicone.

33. The method of claim 22 wherein the transparent protective layer comprises silicone.
